(19) United States
(12) Patent Application Publication
(10) Pub. No.: US 2025/0091941 A1
(43) Pub. Date: Mar. 20, 2025

(54) METHOD OF MANUFACTURING SUBSTRATE

(71) Applicant: Chemtronics Co., Ltd., Sejong (KR)

(72) Inventors: Jaesung PARK, Sejong (KR); Minsoo KIM, Sejong (KR); Mina SHIN, Sejong (KR); Heoncheol SHIN, Sejong (KR)

(73) Assignee: Chemtronics Co., Ltd., Sejong (KR)

(21) Appl. No.: 18/818,886

(22) Filed: Aug. 29, 2024

(30) Foreign Application Priority Data
Sep. 14, 2023 (KR) 10-2023-0122220
Apr. 8, 2024 (KR) 10-2024-0047207
Jun. 12, 2024 (KR) 10-2024-0076507

(51) Int. Cl. C03C 15/00

(52) U.S. Cl. CPC C03C 15/00

(57) ABSTRACT

Disclosed is a method of manufacturing a substrate, the method including attaching a protective film having an adhesive layer formed on one surface thereof onto the substrate, providing an etchant onto the substrate to which the protective film is attached, forming a first flat part, an inclined part, and a second flat part by peeling off an end of the protective film and by changing a reaction surface area between the etchant and the substrate, and removing the protective film.

### CROSS-REFERENCE TO RELATED APPLICATIONS

This application claims priority under 35 U.S.C. § 119 to Korean Patent Application No. 10-2023-0122220 filed on Sep. 14, 2023, Korean Patent Application No. 10-2024-0047207 filed on Apr. 8, 2024, and Korean Patent Application No. 10-2024-0076507 filed on Jun. 12, 2024, in the Korean Intellectual Property Office, the disclosures of which are incorporated by reference herein in their entireties.

### BACKGROUND

Embodiments of the present disclosure described herein relate to a method of manufacturing a substrate.

With the recent development of a display technology, a foldable display, a rollable display, a stretchable display, and the like are being developed.

In particular, a foldable glass is known as a display material that is mainly used in smart phones and other electronic devices in recent several years. The foldable glass may be folded or unfolded, thereby increasing portability, convenience, and durability.

To make the foldable glass, a process of etching a glass to different thicknesses is basically required.

Further, the foldable glass requires basic physical properties of basically satisfying folding characteristics, not having distortion of a screen, and having sufficient strength even in repeated contact with a touch pen and a certain pressure.

### SUMMARY

Embodiments of the present disclosure provide a method of manufacturing a substrate in which, in a cover glass that may be mounted on electronic devices such as portable devices and tablets, a flat part and an inclined part having different thicknesses are formed.

According to an embodiment, a method of manufacturing a substrate includes attaching a protective film having an adhesive layer formed on one surface thereof onto the substrate, providing an etchant onto the substrate to which the protective film is attached, forming a first flat part, an inclined part, and a second flat part by peeling off an end of the protective film and by changing a reaction surface area between the etchant and the substrate, and removing the protective film.

According to an embodiment, a method of manufacturing a substrate includes a first operation of positioning a protective plate on a surface of the substrate to cover a first area on the surface of the substrate with the protective plate, and a second operation of reacting the substrate and an etchant by providing the etchant to a second area of the surface of the substrate except for the first area, wherein, in the second operation, a reaction surface area between the surface of the substrate and the etchant is changed by moving the protective plate on the surface of the substrate.

According to an embodiment, a method of manufacturing a substrate includes a first operation of positioning a plurality of protective plates on a surface of the substrate to cover first areas on the surface of the substrate, and a second operation of reacting the substrate and an etchant by providing the etchant to a remaining second area except for the first areas, wherein, in the second operation, at least some of the plurality of protective plates are moved onto the surface of the substrate to change a reaction surface area between the etchant and the surface of the substrate.

### BRIEF DESCRIPTION OF THE FIGURES

The above and other objects and features of the present disclosure will become apparent by describing in detail embodiments thereof with reference to the accompanying drawings.

FIG. 1 is a perspective view of an etched substrate according to some embodiments of the present disclosure.

FIG. 2 is a cross-sectional view of the etched substrate corresponding to line A-A′ in FIG. 1.

FIG. 3 is a flowchart of a method of manufacturing a substrate according to some embodiments of the present disclosure.

FIGS. 4A to 4E are cross-sectional views sequentially illustrating the method of manufacturing the substrate according to FIG. 3.

FIGS. 5A to 5H are cross sectional views illustrating an angle formed between an inclined part and a second flat part and shapes of a first flat part, the inclined part, and the second flat part, which are changed according to a separation distance and a peeling speed of a protective film, in the substrate manufactured according to the present disclosure.

FIG. 6 is a cross-sectional view illustrating a protective film peeling operation including a peeling controller in the protective film peeling operation of FIG. 3.

FIG. 6A is a perspective view of a roller that may be included in the peeling controller of the present disclosure.

FIG. 6B is a perspective view of a squeeze that may be included in the peeling controller of the present disclosure.

FIG. 7 is a cross-sectional view illustrating a foldable glass that may be formed according to an embodiment of the present disclosure.

FIG. 8 is a cross-sectional view illustrating an embodiment including a chemical liquid controller and a gripping part in the protective film peeling operation of the present disclosure.

FIG. 9 is a cross-sectional view illustrating an embodiment including all the chemical liquid controller, the gripping part, and the peeling controller in the protective film peeling operation of the present disclosure.

FIG. 10 is a flowchart of the method of manufacturing the substrate according to some embodiments of the present disclosure.

FIGS. 11A to 11D are cross-sectional views sequentially showing the method of manufacturing the substrate according to FIG. 10.

FIGS. 12A to 12F are cross-sectional views illustrating an angle formed between the inclined part and the second flat part and the shapes of the first flat part, the inclined part, and the second flat part, which are changed according to a moving speed and a separation distance of a protective plate in the substrate that may be manufactured according to the present disclosure.

FIG. 13 is a plan view illustrating FIG. 11C in a DR2-DR3 plane.

FIGS. 14A and 14B are cross-sectional views illustrating an embodiment including all an etching tank, a protective plate, and a chemical liquid spraying unit, in a protective plate shifting operation of the present disclosure.

FIG. 15 is a plan view illustrating including all the etching tank, the protective plate, and the chemical liquid spraying unit in the DR2-DR3 plane in a protective plate shifting operation S14′ of the present disclosure.

### DETAILED DESCRIPTION

Since the present disclosure may be variously modified and have various forms, an embodiment thereof will be illustrated in the drawings and will herein be described in detail. However, it should be understood that the present disclosure is not limited to a specific disclosure and includes all changes, equivalents, and substitutes included in the spirit and scope of the present disclosure.

The present disclosure relates to a method of manufacturing a substrate that may be used as a cover glass that may be mounted on electronic devices such as portable devices and tablets, and particularly, relates to a method of manufacturing a substrate having different thicknesses.

Hereinafter, an embodiment of the present disclosure will be described in more detail with reference to the accompanying drawings.

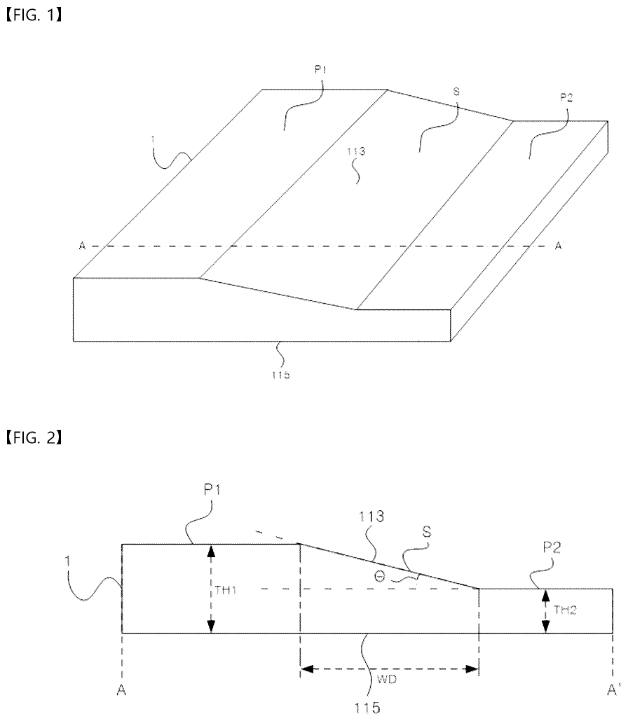

FIG. 1 is a perspective view of an etched substrate 1 according to some embodiments of the present disclosure. FIG. 2 is a cross-sectional view of the etched substrate 1 corresponding to line A-A′ in FIG. 1.

Hereinafter, for convenience of description, a shape of the etched substrate 1 is first described, and then an etching method for manufacturing is described.

Referring to FIGS. 1 and 2, the etched substrate 1 may have both sides having different thicknesses due to etching. A thickness of one side portion of the etched substrate 1 may be greater than a thickness of the other side portion, and an inclination may be formed between both side portions. The etched substrate 1 may include a first surface 113 and a second surface 115 that are opposite to each other. The etched substrate 1 according to the embodiment of the present disclosure may have a rectangular parallelepiped shape. Further, the etched substrate 1 is made of a glass as a raw material, but the present disclosure is not limited thereto. For example, the etched substrate 1 may be manufactured using silicon as a raw material.

The etched substrate 1 may include a first flat part P1, an inclined part “S,” and/or a second flat part P2 on the first surface 113 and/or the second surface 115. Hereinafter, for convenience of description, the shape and a manufacturing method of the etched substrate 1 including the first flat part P1, the inclined part “S” and/or the second flat part P2 on the first surface 113 will be described.

The first flat part P1 may refer to a relatively thick area among an area having a planar shape on the first surface 113 of the etched substrate 1. The first flat part P1 may be positioned on an unetched one side on the first surface 113 of the etched substrate 1. Further, the first flat part P1 may be positioned next to the inclined part “S.” The first flat part P1 may be relatively thick as compared to the second flat part P2.

The inclined part “S” may refer to an area having an inclination on the first surface 113 of the etched substrate 1. The inclined part “S” may be positioned between the first flat part P1 and the second flat part P2 on the first surface 113 of the etched substrate 1. Further, angles Θ and Θ′ between the inclined part “S” and an upper surface of the second flat part P2 may be acute angles.

The second flat part P2 may refer to a relatively thin area among an area having a planar shape on the first surface 113 of the etched substrate 1. The second flat part P2 may be positioned on an etched one side on the first surface 113 of the etched substrate 1. Further, the second flat part P2 may be positioned next to the inclined part “S.” The second flat part P2 may be relatively thin as compared to the first flat part P1.

The first flat part, the second flat part, and the inclined part are illustrated in straight-line cross sections, but this is for convenience of description, and the present disclosure is not limited thereto. In an embodiment of the present disclosure, at least portions of the cross sections of the first flat part, the second flat part, and the inclined part may be formed in curved lines. Further, portions of the first flat part, the second flat part, and the inclined part may be omitted. For example, one surface of the substrate may include only the inclined part or may include only the first flat part and the inclined part. Further, the one surface of the substrate may include only the second flat part and the inclined part without the first flat part.

As will be described below, depending on a position in which a substrate is etched, the first flat parts P1 may be present on both sides of the first surface 113 of the substrate, and an area of the inclined part “S” and the second flat part P2 and an area of the inclined part “S” may be present side by side therebetween. Because the etched substrate having this shape may be easily folded in an area in which the inclined part and the second flat part are formed, the etched substrate will be referred to as a foldable substrate 111 below in consideration of this.

Further, in the foldable substrate 111, the inclined part “S” and the second flat part P2 and the inclined part “S” that may be present on the first surface 113 side by side are collectively referred to as a folding part “F.”

For the etched substrate 1 that may be manufactured according to the present disclosure, a thickness TH1 of the first flat part may have various values. For example, the thickness TH1 of the first flat part P1 may be in a range of about 30 μm to about 500 μm, about 40 μm to about 300 μm, or about 50 μm to about 200 μm.

For the etched substrate 1 that may be manufactured according to the present disclosure, widths WD and WD′ of the inclined part may have various values. For example, the widths WD and WD′ of the inclined part may be in a range of about 0.5 mm to about 30 mm.

For the etched substrate 1 that may be manufactured according to the present disclosure, the angles Θ and Θ′ formed between the inclined part and the upper surface of the second flat part may have various values. For example, the angles Θ and Θ′ formed between the inclined part and the upper surface of the second flat part may be in a range of about 0.3° to about 10°.

For the etched substrate 1 that may be manufactured according to the present disclosure, a thickness TH2 of the second flat part may have various values. For example, the thickness TH2 of the second flat part may be in a range of about 10 μm to about 100 μm, about 20 μm to about 80 μm, or about 30 μm to about 70 μm.

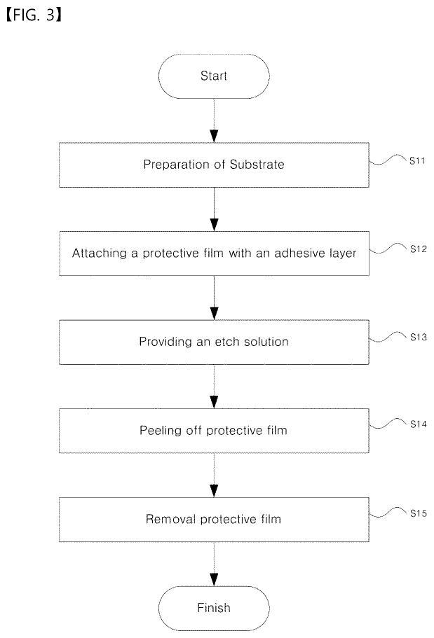

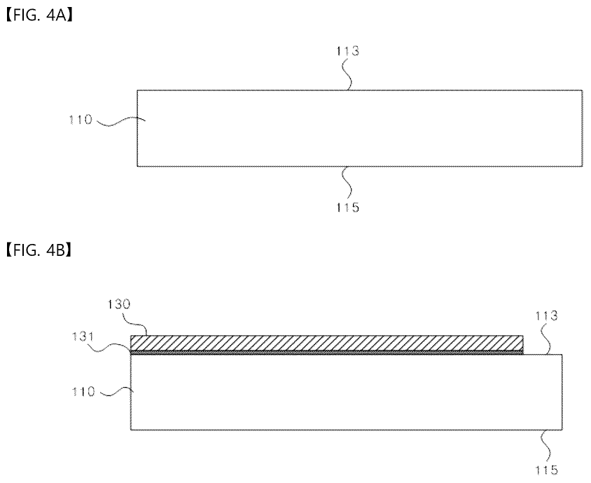

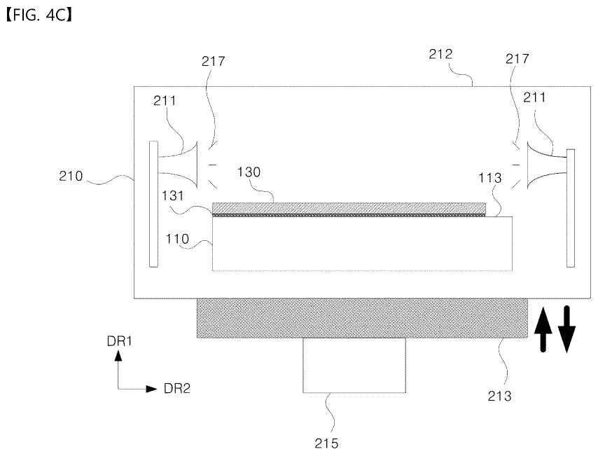

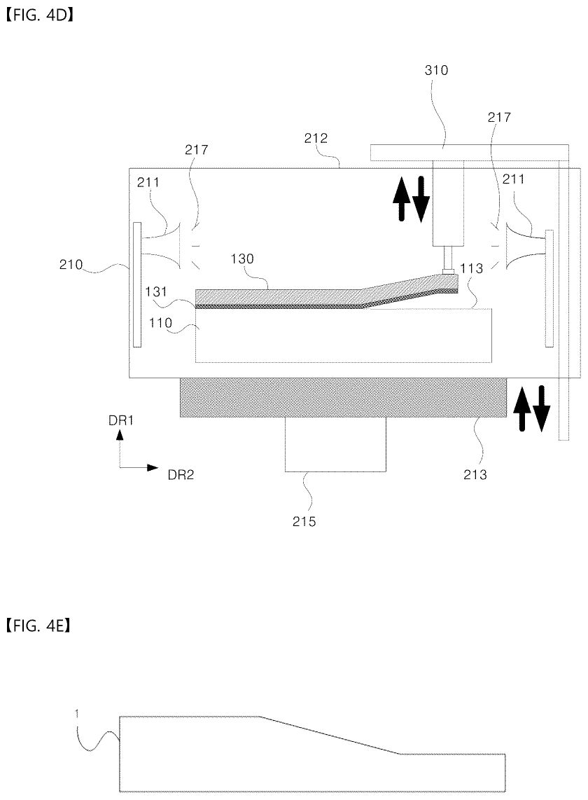

FIG. 3 is a flowchart of a method of manufacturing a substrate according to some embodiments of the present disclosure, and FIGS. 4A to 4E are cross-sectional views sequentially illustrating the method of manufacturing the substrate according to FIG. 3.

Hereinafter, operations of the method of manufacturing the substrate according to FIG. 3 will be described in detail.

The operations of the method of manufacturing the substrate according to FIG. 3 may sequentially include a glass substrate preparing operation S11, an adhesive layer-formed protective film attaching operation S12, an etchant providing operation S13, and a protective film peeling operation S14.

Referring to FIG. 4A, in the glass substrate preparing operation S11, a substrate 110 in an unetched state may be prepared.

In the embodiment of the present disclosure, the substrate 110 may have a rectangular parallelepiped shape, but the present disclosure is not limited thereto. For example, the substrate 110 may also have a cylindrical shape.

Further, the substrate 110 may be made of glass as a raw material, but the present disclosure is not limited thereto. For example, the substrate 110 made of silicon or rubber as a raw material may be prepared.

The substrate 110 may be etched by a process through the above-described operations and manufactured into the etched substrate 1. As described above, the etched substrate 1 is made of glass as a raw material, but the present disclosure is not limited thereto.

Referring to FIG. 4B, in the adhesive layer-formed protective film attaching operation S12, after an adhesive layer 131 may be formed on one surface of a protective film 130, and the protective film 130 on which the adhesive layer is formed may be attached to the first surface 113 of the substrate 110.

The adhesive layer 131 may refer to a layer on which an adhesive is applied to one surface of the protective film. The adhesive layer 131 may be positioned between the one surface of the protective film and the first surface of the substrate. The adhesive layer 131 may function to allow the protective film 130 to be attached to the substrate 110. Accordingly, the adhesive layer 131 may be made of a material that may adhere the substrate 110 and the protective film 130. The adhesive layer 131 may be made of a material that is not etched by an etchant 217. A forming method for the adhesive layer 131 is not limited. For example, the forming method may be application of an adhesive or attachment of an adhesive tape.

Further, a peeling speed at an end of the protective film 130 may be controlled according to an adhesive force of the adhesive layer 131. For example, when the adhesive force of the adhesive layer 131 is strong, the peeling speed when the same force is applied to the end of the protective film 130 may be relatively slow, and in contrast, when the adhesive force of the adhesive layer 131 is weak, the peeling speed when the same force is applied to the end of the protective film 130 may be relatively fast.

The protective film 130 may be attached to the first surface 113 of the substrate 110. The protective film 130 may have a rectangular parallelepiped shape that is the same as the substrate 110. The protective film 130 may prevent a glass substrate from being etched by the etchant 217. As will be described below, the etchant 217 may be made of a material that has a property of etching the substrate 110. Thus, the protective film 130 may be made of a material that is not etched by the etchant 217. For example, the protective film 130 may be acid resistant.

Referring to FIG. 4C, in the etchant providing operation S13, the substrate 110 undergoing the protective film attaching operation S12 is positioned inside a chamber 212. In this case, the etchant 217 may be provided to the substrate 110 positioned inside the chamber 212 through a chemical liquid controller 210.

The etchant 217 may etch the substrate 110. Although not separately illustrated in the drawing, the etchant 217 may be stored in an etchant storing unit. The etchant storing unit may be connected to a chemical liquid spraying nozzle 211 through a separate line. A position of the etchant storing unit is not limited. For example, the etchant storing unit may be present in an external space other than the chamber 212 and a chamber support 213.

The etchant 217 may be provided to the substrate 110 in various forms. For example, the etchant 217 may be provided to the substrate 110 through the chemical liquid spraying nozzle 211. Further, the etchant 217 provided through the chemical liquid spraying nozzle 211 may be stored in the chamber 212. Accordingly, the substrate 110 may be immersed using the etchant 217 stored in the chamber 212.

The substrate 110 may be etched when the etchant 217 is provided thereto. The etchant 217 may be made of a material that has a property of etching the substrate 110. For example, it is assumed that the material of the substrate 110 is glass. In this case, the etchant 217 may contain a fluoride salt, a sulfate, a nitrate, a hydrofluoric acid, a sulfuric acid, and/or a nitric acid. In this case, the etchant 217 may be acidic. The glass may be etched by an acidic solution. The etchant 217 may serve to etch the substrate 110. The protective film 130 and the adhesive layer 131 may be made of an acid-resistant material (e.g., quartz, plastic, or the like). Thus, a portion of the substrate 110, to which the protective film 130 is attached, may not be etched by the acidic etchant 217. Further, a portion of the first surface 113 of the substrate 110, from which the protective film 130 is peeled off, and a portion of the substrate 110, to which the protective film 130 is not attached, may be exposed to the etchant 217 and etched by the etchant 217. The inclined part “S” and the second flat part P2 may be formed on the substrate 110 through this selective etching process.

The chemical liquid controller 210 may include the chemical liquid spraying nozzle 211, the chamber 212, the chamber support 213, and a motor 215.

The chemical liquid spraying nozzle 211 may be a nozzle that may spray the etchant 217. The chemical liquid spraying nozzle 211 may be positioned on a side surface or the first surface 113 of the substrate 110. Referring to FIG. 4C, it is illustrated that the number of chemical liquid spraying nozzles is two, but the present disclosure is not limited thereto. In another embodiment of the present disclosure, a different number from the illustration, for example, one or three or more chemical liquid spraying nozzles 211, may be positioned on the side surface or the first surface 113 of the substrate 110.

The chemical liquid spraying nozzle 211 may provide the etchant 217 to the first surface 113 of the substrate 110 in a spraying manner.

Further, the chemical liquid spraying nozzle 211 may adjust a spraying intensity and direction of the etchant 217, a flow rate and direction of the etchant 217 may be adjusted, and therefore, the chemical liquid spraying nozzles 211 may adjust a degree of etching of the substrate 110. For example, in the chemical liquid spraying nozzle 211, when the spraying intensity of the etchant 217 is increased, the flow rate of the etchant 217 may be increased, and the amount of etchant 217 provided to the substrate 110 per unit time may be increased. In this case, the degree of etching of the substrate 110 may be increased.

The chamber 212 may provide a space in which the glass substrate is etched. The chamber 212 may be positioned on the chamber support 213. The chamber 212 may be provided in a form that is open on one side (e.g., an upper side) or may be provided in a form that is closed on all sides. The substrate 110 to be etched and components required for etching the substrate 110 may be provided inside the chamber 212. For example, the protective film 130, the adhesive layer 131, the substrate 110, the etchant 217, the chemical liquid spraying nozzle 211, and a gripping part 310 may be provided inside the chamber 212, and according to the embodiment of the present disclosure, a peeling controller 410 may be additionally provided.

The chamber support 213 may be a support container that serves to support the chamber 212. The chamber support 213 may be connected to a lower surface of the chamber 212.

As indicated by an arrow illustrated in FIG. 4C, the chamber 212 may be vibrated through movement of the chamber support 213 in a first direction DR1 perpendicular to the ground and in a direction opposite to the first direction DR1. Accordingly, the degree of provision of the etchant 217 on the substrate 110 may be changed, and slurry formed on the substrate 110 during the etching process may be removed. Therefore, the degree of etching of the substrate 110 may be adjusted, and more uniform etching may be achieved. The direction of movement of the chamber support 213 according to the embodiment of the present disclosure is the first direction DR1 and the direction opposite to the first direction DR1, but the present disclosure is not limited thereto. For example, the chamber 212 may be vibrated through movement of the chamber support 213 in a second direction DR2 or a direction opposite to the second direction DR2.

The motor 215 may be a control device that controls spraying and/or movement of the chemical liquid spraying nozzle 211. The motor 215 may be connected to the chamber support 213 and the chemical liquid spraying nozzle 211.

The motor 215 may be driven to provide power to the chemical liquid spraying nozzle 211. Therefore, a height, a direction, and/or a spraying speed of the chemical liquid spraying nozzle 211 may be adjusted, and for the first time, the flow rate and direction of the etchant 217 may be adjusted.

Referring to FIG. 4D, in the protective film peeling operation S14, the end of the protective film 130 may be gripped by the gripping part 310. The gripping part 310 may peel the protective film 130 in the first direction DR1 perpendicular to the ground. As the protective film 130 is peeled off, the etchant 217 provided through the chemical liquid controller 210 may be exposed to a portion or the entirety of the first surface 113 of the substrate 110. Accordingly, the substrate 110 may be etched to form the etched substrate 1.

The gripping part 310 may grip the end of the protective film 130 and space the end of the protective film 130.

The gripping part 310 may be driven inside the chamber 212. The gripping part 310 may be located either inside or outside the chamber 212.

The gripping part 310 may have one end facing the protective film 130. One end of the gripping part 310 may be in contact with an upper surface of the protective film 130 and grip the end of the protective film 130. Through movement of the gripping part 310 in the first direction DR1 perpendicular to the ground, the protective film 130 may be peeled off in the first direction DR1 so as to space the end of the protective film 130 apart from the first surface 113 of the substrate 110.

Further, although not illustrated, the gripping part 310 may be provided with a separate power device such as a motor, and thus a moving speed or moving direction of the gripping part 310 may be controlled. For example, as indicated by an arrow illustrated in FIG. 4D, the moving speed of the gripping part 310 in the first direction DR1 may be controlled, and thus a speed at which the protective film 130 is peeled off from the first surface 113 of the substrate 110 may be controlled. Therefore, a spacing speed of the end of the protective film 130 may be controlled.

However, the moving direction of the gripping part 310 is not necessarily limited to the direction of the arrow illustrated in FIG. 4D and may be controlled in other directions. For example, the gripping part 310 may move in a direction forming an acute angle with respect to the ground to peel off the protective film 130.

Further, although not illustrated, the gripping part 310 may be provided with a separate gripping guide substrate so that the gripping part 310 may easily perform the gripping. For example, the separate gripping guide substrate may be attached to a gripping portion of the gripping part 310, and a desired gripping portion on the protective film 130 in accordance with the gripping guide substrate may be gripped.

FIG. 4E is a cross-sectional view of the etched substrate 1 undergoing a protective film removing operation S15 in the present disclosure.

Referring to FIG. 4E, in the protective film removing operation S15, the protective film 130 attached to the etched substrate 1 may be removed. Further, after the series of operations according to the manufacturing method of the present disclosure, the etched substrate 1 may be chemically strengthened. For example, when the etched substrate 1 is made of glass, a glass substrate may be immersed in a molten salt tank containing metal positive ions, which are greater than metal positive ions present in the glass substrate, and thus, the chemical strengthening that substitutes the metal positive ions inside the glass substrate with the greater metal positive ions may be performed. In this case, a compressive stress (CS) may be generated inside the glass substrate. Thus, a strength of the glass substrate against an external impact may be increased.

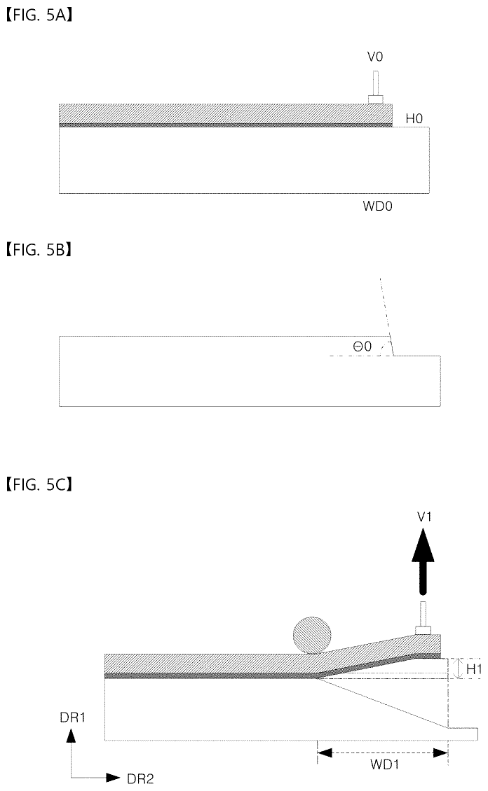

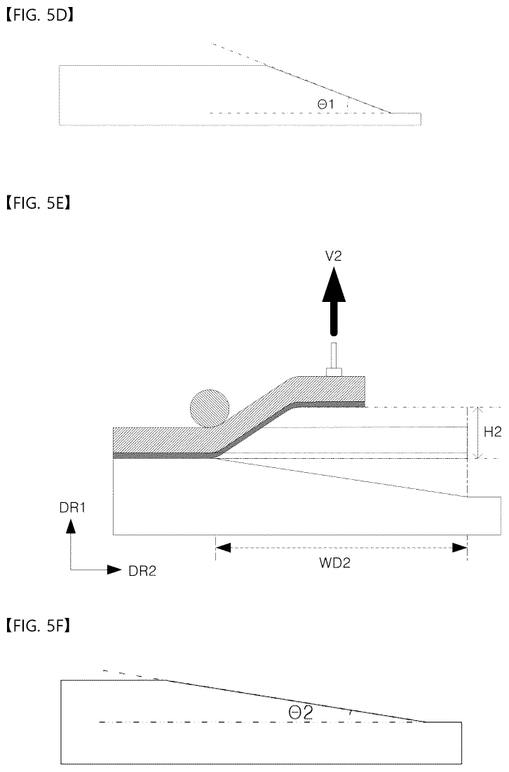

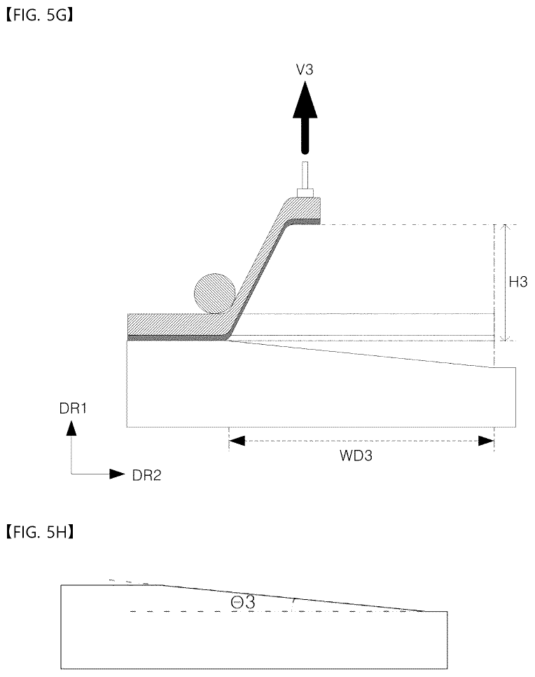

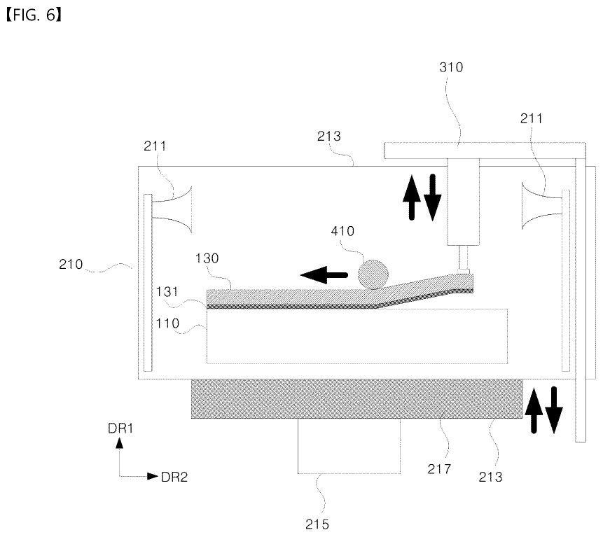

FIGS. 5A to 5H are cross sectional views illustrating an angle Θ formed between the inclined part “S” and the second flat part P2 and the shapes of the inclined part, the first flat part, and the second flat part, which are changed according to a separation distance and a peeling speed of the protective film, in the substrate manufactured according to the present disclosure.

According to the embodiment of the present disclosure, when the separation distance of the protective film 130 is changed, a surface area of the substrate 110 exposed to the etchant 217 may be changed, and accordingly, the degree of etching on the substrate 110 may be changed. In this case, the width WD of the inclined part “S” formed on the substrate 110 may be changed. For example, when the separation distance of the protective film 130 is increased, the surface area of the substrate 110 to which the etchant 217 is provided is increased at a spaced portion of the protective film 130. That is, the etched area on the substrate 110 may be increased. Thus, the width WD of the inclined part “S” formed on the substrate 110 may be increased. In contrast, when the separation distance of the protective film 130 is decreased, the surface area of the substrate 110 to which the etchant 217 is provided is decreased at the spaced portion of the protective film 130. That is, the etched area on the substrate 110 may be decreased. Thus, the width WD of the inclined part “S” formed on the substrate 110 may be decreased.

When the peeling speed of the protective film 130 is changed, the amount of the etchant 217 provided on the substrate 110 may be changed as the protective film 130 is peeled off in the first direction DR1 perpendicular to the ground, and accordingly, the degree of etching on the substrate 110 may be changed. In this case, the angle Θ formed between the inclined part “S” and the second flat part P2 formed on the substrate 110 may be changed. For example, when the peeling speed of the protective film 130 is fast, the protective film 130 is spaced, and thus a time interval during which the substrate 110 is exposed to the etchant 217 is decreased for each portion in which the substrate 110 is exposed to the etchant 217. Accordingly, the etching is uniformly performed, and thus the angle Θ between the inclined part “S” and the second flat part P2 formed on the substrate 110 may be decreased. Further, when the peeling speed of the protective film 130 is slow, the protective film 130 is spaced, and thus a time interval during which the substrate 110 is exposed to the etchant 217 is increased for each portion in which the substrate 110 is exposed to the etchant 217. Accordingly, the etching is unevenly performed, and thus the angle Θ between the inclined part “S” and the second flat part P2 formed on the substrate 110 may be increased.

FIGS. 5A, 5C, 5E, and 5G are cross-sectional views illustrating an etched substrate that may be manufactured according to the present disclosure when the peeling speeds of the protective film are V0, V1, V2, and V3 and the separation distances thereof are H0, H1, H2, and H3.

FIG. 5B is a cross-sectional view of the etched substrate 1 that may be formed when the peeling speed is set to V0 and the separation distance is set to H0 in FIG. 5A.

FIG. 5D is a cross-sectional view of the etched substrate 1 that may be formed when the peeling speed is set to V1 and the separation distance is set to H1 in FIG. 5C.

FIG. 5F is a cross-sectional view of the etched substrate 1 that may be formed when the peeling speed is set to V2 and the separation distance is set to H2 in FIG. 5E.

FIG. 5H is a cross-sectional view of the etched substrate 1 that may be formed when the peeling speed is set to V3 and the separation distance is set to H3 in FIG. 5G.

As described above, the angle Θ formed between the inclined part “S” and the second flat part P2 may be affected by the peeling speed of the protective film 130. For example, as the peeling speed of the protective film 130 is increased, the angle Θ formed between the inclined part “S” and the second flat part P2 may be decreased.

As described above, the width of the inclined part “S” may be affected by the separation distance of the protective film 130. For example, as the separation distance of the protective film 130 is increased, the width of the inclined part “S” may be increased.

Comparing the peeling speeds and the separation distances of the protective film 130 illustrated in FIGS. 5A, 5C, 5E, and 5G, V0<V1<V2<V3 and/or H0<H1<H2<H3.

Comparing widths of the inclined part formed in the protective film 130 illustrated in FIGS. 5A, 5C, 5E, and 5G, WD0<WD1<WD2<WD3. Thus, as the separation distance of the protective film 130 is increased, the width of the inclined part “S” may be increased.

Comparing the angles formed between the inclined part “S” and the second flat part P2 illustrated in FIGS. 5B, 5D, 5F, and 5H, Θ0>Θ1>Θ2>Θ3. Thus, as the peeling speed of the protective film 130 is increased, an inclination of the inclined part “S” may become gradually gentle.

In the present disclosure, using this principle, through movement of the gripping part 310 in the first direction DR1 and the direction opposite to the first direction DR1, the peeling speed and the separation distance of the protective film 130 may be controlled, thereby adjusting the degree of etching on the substrate 110. Therefore, the substrate 110 may be etched to form the etched substrate 1 having different thicknesses on both sides thereof.

In the embodiment of the present disclosure, the substrate 110 may be etched using the above-described method, and thus the etched substrate 1 having different thicknesses depending on areas thereof may be manufactured.

In the embodiment of the present disclosure, the peeling controller 410 may be used in the protective film peeling operation S14.

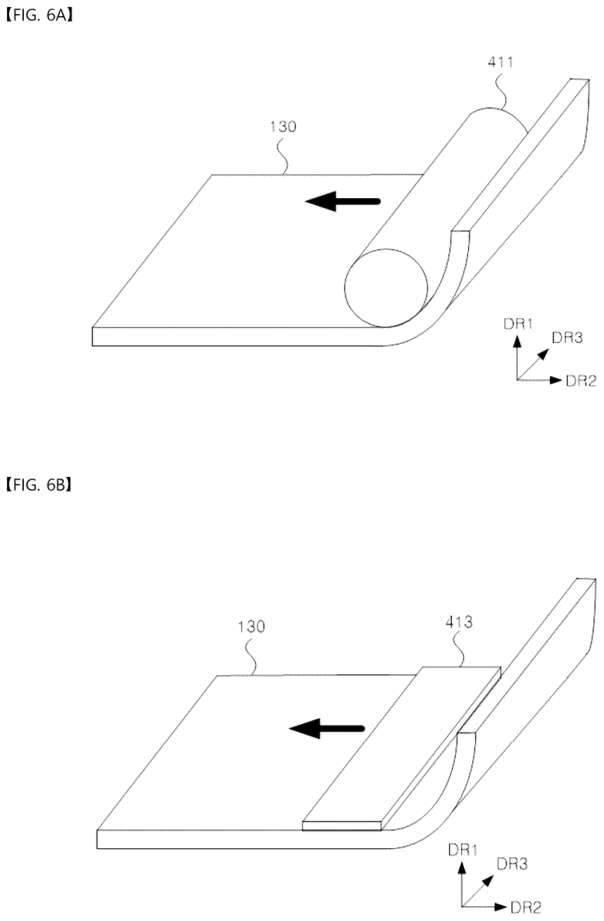

FIG. 6 is a cross-sectional view illustrating the protective film peeling operation S14 including the peeling controller 410 in the protective film peeling operation S14 of FIG. 3.

The peeling controller 410 is a device that controls the peeling of the protective film 130. In more detail, the peeling controller 410 is a device that controls separation when the protective film 130 is peeled off by the movement of the gripping part 310 in the protective film peeling operation S14 of the present disclosure.

The peeling controller 410 may be in contact with an upper surface of the protective film 130. The peeling controller 410 may apply a force in the direction opposite to the first direction DR1 perpendicular to the ground, to compress the spaced portion of the protective film 130. Therefore, in the protective film peeling operation S14, the separation distance and the peeling speed of the protective film 130 may be controlled.

Further, the peeling controller 410 may be positioned on the protective film 130 and move in the second direction DR2 parallel to the ground or the direction opposite to the second direction DR2. Therefore, the separation may be controlled in accordance with the separation distance and the peeling speed of the protective film 130. For example, it is assumed that the etched substrate 1 is manufactured by etching the substrate 110. In this case, the protective film 130 may be peeled off in the first direction DR1 by the gripping part 310, and at the same time, the peeling controller 410 may move in the direction opposite to the second direction DR2. In this manner, the separation may be controlled in accordance with the separation distance of the protective film 130.

FIG. 6A is a perspective view illustrating a roller 411 that may be the peeling controller 410 of the present disclosure. The roller 411 may be positioned on the protective film 130 and apply a force in the direction opposite to the first direction DR1 perpendicular to the ground through a rolling motion, to compress the spaced portion of the protective film 130. Further, at the same time, the roller 411 may move in the second direction DR2 parallel to the ground or the direction opposite to the second direction DR2, and thus the separation may be controlled in accordance with the separation distance of the protective film 130.

FIG. 6B is a perspective view illustrating a squeeze 413 that may be the peeling controller 410 of the present disclosure. The squeeze 413 may be positioned on the protective film 130 and apply a force in the direction opposite to the first direction DR1 perpendicular to the ground to the protective film 130, to compress the spaced portion of the protective film 130. Further, at the same time, the squeeze 413 may move in parallel in the second direction DR2 or the direction opposite to the second direction DR2, and thus the separation may be controlled in accordance with the separation distance of the protective film 130.

According to FIG. 6A or FIG. 6B, the peeling controller 410 may be the roller or the squeeze, but this merely illustrates the embodiment of the peeling controller 410, and the present disclosure is not limited thereto.

According to the embodiment of the present disclosure, the method of manufacturing the substrate having different thicknesses depending on areas thereof may be used to manufacture the foldable substrate 111.

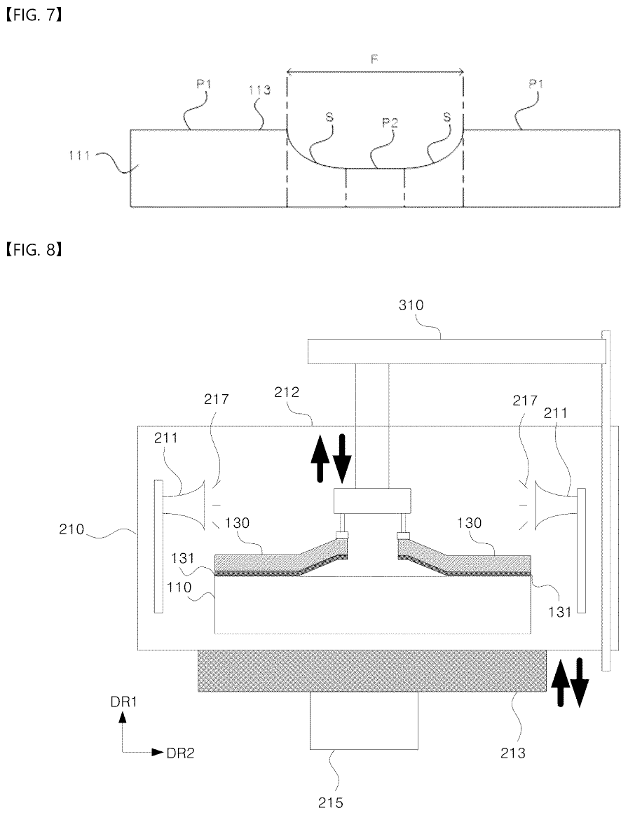

FIG. 7 is a cross-sectional view illustrating the foldable substrate 111 that may be formed according to the embodiment of the present disclosure. In the foldable substrate 111, the folding part “F” may be formed in any part of a first surface of the foldable substrate 111.

The foldable substrate 111 is made of a glass as a raw material, but the present disclosure is not limited thereto. For example, the foldable substrate 111 may be manufactured using silicon as a raw material.

Hereinafter, a foldable glass that may be manufactured according to the embodiment of the present disclosure will be described.

The foldable glass may refer to a foldable cover glass. The foldable glass may include flat parts on both sides of one surface thereof and include an inclined part and a second flat part having different thicknesses between the two flat parts.

The foldable glass requires basic physical properties of basically satisfying folding characteristics, not having distortion of a screen, and having sufficient strength even in repeated contact with a touch pen and a certain pressure.

To satisfy strength characteristics of the foldable glass, the glass should have a certain thickness or more, and to satisfy folding characteristics, the glass should have a certain thickness or less. Thus, a manufacturing method of forming an optimum glass thickness and structure that satisfies the strength characteristics and the folding characteristics without distortion of a screen is required.

For the foldable substrate 111 that may be manufactured according to the present disclosure, the thickness TH1 of the first flat part may have various values. For example, the thickness TH1 of the first flat part P1 may be in a range of about 30 μm to about 500 μm, about 40 μm to about 300 μm, or about 50 μm to about 200 μm.

For the foldable substrate 111 that may be manufactured according to the present disclosure, the width WD of the inclined part may have various values. For example, the width WD of the inclined part may be in a range of about 0.5 mm to about 30 mm.

For the foldable substrate 111 that may be manufactured according to the present disclosure, the angle Θ formed between the inclined part and the upper surface of the second flat part may have various values. For example, the angle Θ formed between the inclined part and the upper surface of the second flat part may be in a range of about 0.3° to about 10°.

For the foldable substrate 111 that may be manufactured according to the present disclosure, the thickness TH2 of the second flat part may have various values. For example, the thickness TH2 of the second flat part may be in a range of about 10 μm to about 100 μm, about 20 μm to about 80 μm, or about 30 μm to about 70 μm.

According to the embodiment of the present disclosure, the foldable substrate 111 having a thickness that may satisfy both the folding characteristics and the strength characteristics may be manufactured. Further, the foldable substrate 111 may maintain product performance even while being bent. Thus, damage that occurs due to cracking in a process of making the substrate 110 thin may be improved.

As the width of the inclined part of the glass substrate is decreased or the angle between the inclined part and the second flat part is increased, the degree of reflection of light in the inclined part and a boundary between the flat part and the inclined part may be increased. As a result, visibility of the glass substrate may be degraded.

In the foldable substrate 111 that may be manufactured through the embodiment of the present disclosure, the folding part “F” having a desired shape may be formed. That is, the width of the inclined part “S” may be increased, and the angle between the inclined part “S” and the second flat part P2 may be decreased. Accordingly, visibility of a reflective surface in the inclined part “S” may be improved, and screen distortion or visibility of the boundary may be minimized.

FIG. 8 is a cross-sectional view illustrating an embodiment in which, in the protective film peeling operation S14, the chemical liquid controller 210 and the gripping part 310 are included, both sides of the protective film 130 is gripped and then peeled off, and thus the folding part “F” is formed at a portion of the substrate 110.

According to the embodiment of FIG. 8, the etchant 217 may be provided to the substrate 110 through the chemical liquid controller 210. In this case, both sides of the protective film 130 attached to the substrate 110 may be gripped through the gripping part 310. The protective film 130 may be peeled off in the first direction DR1 through the gripping part 310. The peeling speed and the separation distance may be adjusted through movement of the gripping part 310 in the first direction DR1 and in the direction opposite to the first direction DR1.

Arrows illustrated in FIG. 8 illustrate a vibration direction of the chemical liquid controller 210 and a movement direction of the gripping part 310, and the vibration speed and the moving speed may be the same or different. However, the vibration direction of the chemical liquid controller 210 and the moving direction of the gripping part 310 are not limited to directions of the arrows illustrated in FIG. 8 and may be controlled in other directions. For example, the gripping part 310 may move in a direction forming an acute angle with respect to the ground to peel off the protective film 130.

According to the embodiment of FIG. 8, the folding part “F” may be formed at a portion of the substrate 110. Accordingly, the foldable substrate 111 on which the folding part “F” of having a desired shape is formed may be manufactured.

The folding part “F” having a desired shape may be formed in the foldable substrate 111 manufactured through the embodiment of FIG. 8. Accordingly, visibility of a reflective surface in the inclined part “S” may be improved, and screen distortion or visibility of the boundary may be minimized.

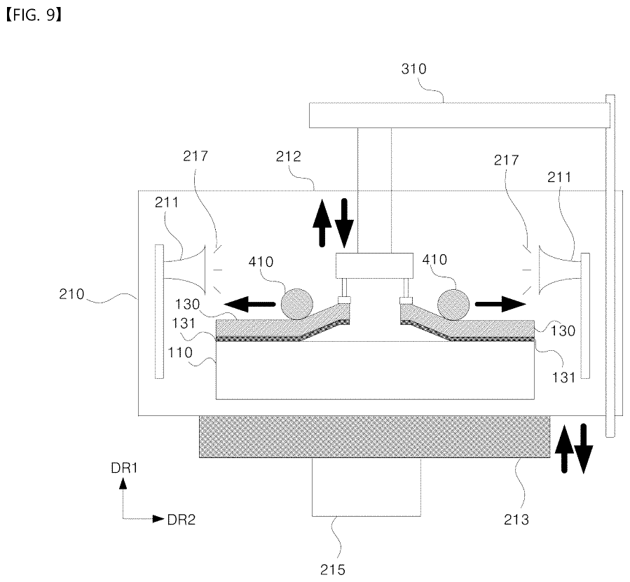

FIG. 9 is a cross-sectional view illustrating an embodiment that additionally includes the peeling controller 410 in FIG. 8.

According to the embodiment of FIG. 9, the etchant 217 may be provided to the substrate 110 through the chemical liquid controller 210. Further, both sides of the protective film 130 attached to the substrate 110 may be gripped through the gripping part 310. The protective film 130 may be peeled off in the first direction DR1 through the gripping part 310. At the same time, a force may be applied to the protective film 130 in the second direction DR2 and the direction opposite to the second direction DR2 through the peeling controller 410. Accordingly, the peeling speed and the separation distance of the protective film 130 may be adjusted.

Arrows illustrated in FIG. 9 illustrate the vibration direction of the chemical liquid controller 210, the moving direction of the gripping part 310, and the moving direction of the peeling controller 410, and the vibration speed and the moving speeds may be the same or different. However, the vibration direction of the chemical liquid controller 210, the moving direction of the gripping part 310, and the moving direction of the peeling controller 410 are not necessarily limited to directions of the arrows illustrated in FIG. 9 and may be controlled in other directions. For example, the peeling speed and the separation distance of the protective film 130 may be adjusted by moving the peeling controller 410 in a direction forming an acute angle with the ground.

According to the embodiment of FIG. 9, the folding part “F” may be formed at a portion of the substrate 110. Accordingly, the foldable substrate 111 on which the folding part “F” of having a desired shape is formed may be manufactured.

The folding part “F” having a desired shape may be formed on the foldable substrate 111 manufactured through the embodiment of FIG. 9. Accordingly, visibility of a reflective surface in the inclined part “S” may be improved, and screen distortion or visibility of the boundary may be minimized.

A difference between FIGS. 9 and 8 is the presence or absence of the peeling controller 410, and accordingly, FIG. 9 is more advantageous in terms of adjusting the peeling speed and the separation distance.

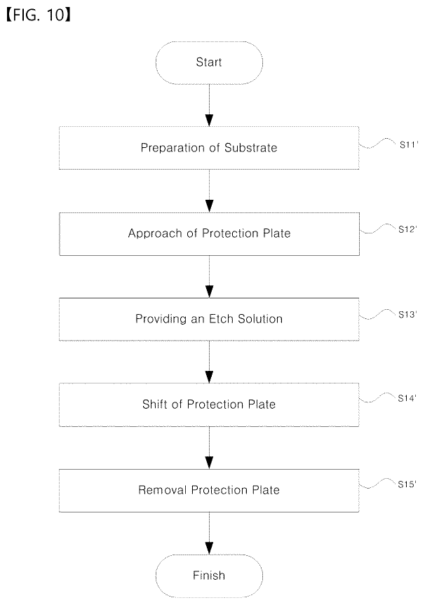

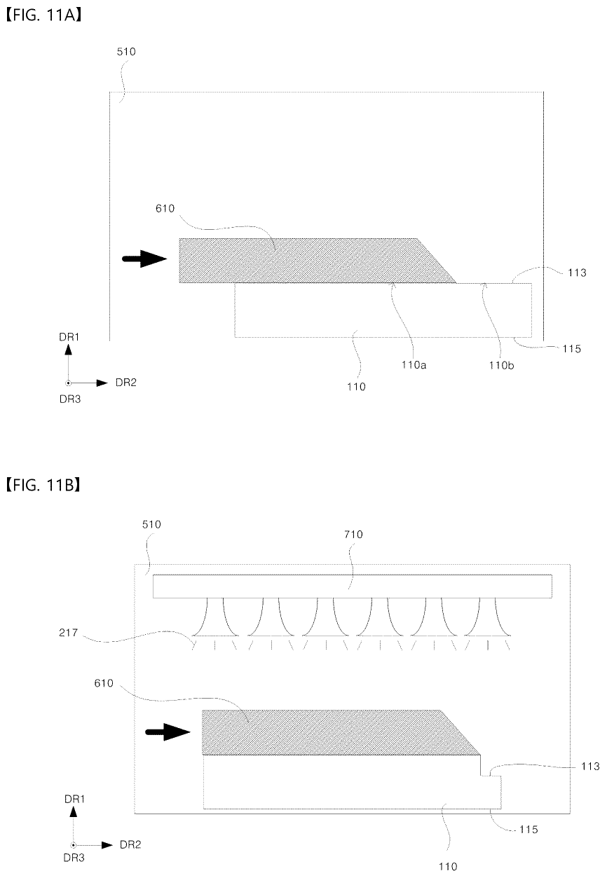

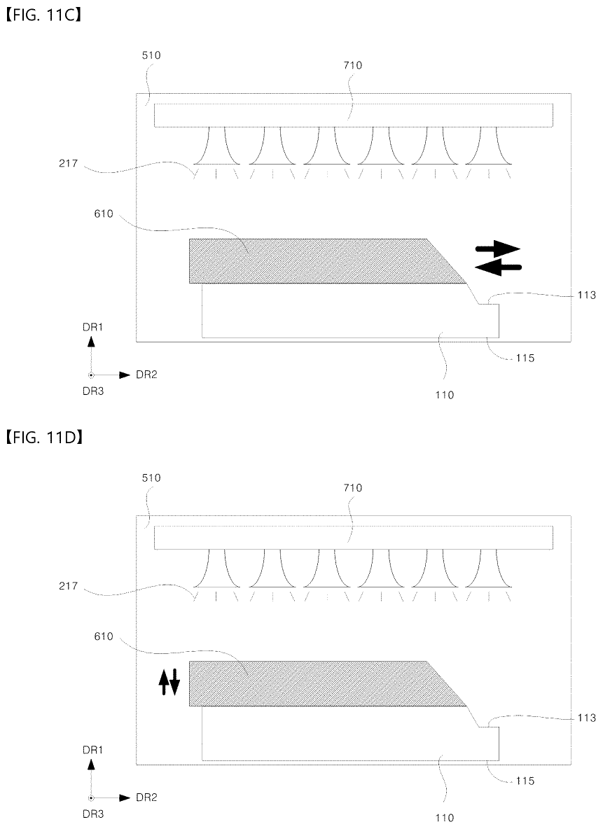

FIG. 10 is a flowchart of a method of manufacturing a substrate according to some embodiments of the present disclosure, and FIGS. 11A to 11D are cross-sectional views sequentially illustrating the method of manufacturing the substrate according to FIG. 10.

Like the manufacturing method according to FIGS. 4A to 4E, the etched substrate 1 may be obtained through the method of manufacturing the substrate according to FIGS. 11A to 11D. The shape of the etched substrate 1 has been described above, and thus operations of the method of manufacturing the substrate according to FIG. 10 will be described below in detail. For convenience of description, differences between the manufacturing method of FIG. 3 and the present manufacturing method will be mainly described. Further, for convenience of description, the method of manufacturing the substrate on which the first surface 113 is etched will be described, but the present disclosure is not limited thereto. For example, the etched substrate 1 may be manufactured by etching the second surface 115 or the side surface of the substrate.

The operations of the method of manufacturing the substrate according to FIG. 10 sequentially include a glass substrate preparing operation S11′, a protective plate introducing operation S12′, an etchant providing operation S13′, a protective plate shifting operation S14′, and a protective plate removing operation S15′.

Referring to FIG. 11A, in the glass substrate preparing operation S11′, the substrate 110 in an unetched state may be prepared.

Referring to FIG. 11A, in the protective plate introducing operation S12′, the substrate 110 may be positioned in an etching tank 510. Thereafter, a protective plate 610 may be introduced onto the first surface 113 of the substrate 110.

A first area 110a on the first surface 113 of the substrate 110 may be covered with the protective plate 610. Accordingly, the first surface 113 of the substrate 110 may be defined as the first area 110a covered with the protective plate 610 and a second area 110b not covered with the protective plate 610.

Features of the substrate 110 of FIG. 11A may be the same as/similar to corresponding features of the substrate 110 of FIG. 4A.

The etching tank 510 may provide a space in which etching of the substrate 110 is performed. The etching tank 510 may be provided in a form that is open on one side (e.g., an upper side) or may be provided in a form that is closed on all sides. The substrate 110 to be etched and the components required for etching the substrate 110 may be provided in the etching tank 510. For example, the substrate 110, the etchant 217, the protective plate 610, and a chemical liquid spraying unit 710 may be provided in the etching tank 510.

The protective plate 610 may be positioned on the first surface 113 of the substrate 110. The protective plate 610 may have a rectangular parallelepiped shape that is the same as the substrate 110. The protective plate 610 may prevent the substrate 110 from being etched by the etchant 217. The protective plate 610 may include a material that is not etched by the etchant 217. For example, the protective plate 610 may include an acid-resistant material (e.g., quartz or plastic).

A separate controller (not illustrated) may be connected to a portion of the protective plate 610. The controller (not illustrated) may move and space the protective plate 610 through driving. For example, the protective plate 610 may be introduced onto the first surface 113 of the substrate 110 through the driving of the controller (not illustrated).

Referring to FIG. 11B, in the etchant providing operation S13′, the etchant 217 may be provided to the second area 110b of the substrate 110. The second area 110b of the substrate 110 may react with the etchant 217. On the other hand, the etchant 217 may not be provided to the first area 110a of the substrate 110, which is covered with the protective plate 610.

The etchant 217 may react with the substrate 110 to etch the substrate 110. The etchant 217 may be made of a material that has a property of etching the substrate 110. In addition, features of the etchant 217 may be the same as/similar to corresponding features of the etchant 217 of FIG. 4C.

The etchant 217 may be provided to the substrate 110 in various forms. For example, the etchant 217 may be stored in a separate etchant storing unit (not illustrated) and provided to the etching tank 510 through a separate line (not illustrated). Accordingly, the substrate 110 may be immersed using the etchant 217 provided inside the etching tank 510.

Further, the etchant 217 may be provided to the substrate 110 through the chemical liquid spraying unit 710. The chemical liquid spraying unit 710 is a device that may spray the etchant 217. The chemical liquid spraying unit 710 may be positioned on an upper side or a side surface of the first surface 113 of the substrate 110.

The chemical liquid spraying unit 710 may adjust a spraying pressure, a spraying speed, and/or a spraying position of the etchant 217 by adjusting a temperature, a spraying intensity, and/or a spraying direction of the etchant 217. Therefore, the chemical liquid spraying unit 710 may adjust the degree of etching of the substrate 110. For example, when the chemical liquid spraying unit 710 increases the spraying intensity of the etchant 217, the spraying speed of the etchant 217 may be increased, and the amount of the etchant 217 provided to the substrate 110 per unit time may be increased. In this case, the degree of etching of the substrate 110 may be increased.

Referring to FIGS. 11C and 11D, in the protective plate shifting operation S14′, the protective plate 610 may be spaced in the first direction DR1 perpendicular to the substrate 110 or the direction opposite to the first direction DR1 or may be moved in the second direction DR2 parallel to the substrate 110 or the direction opposite to the second direction DR2. The spacing of the protective plate 610 and/or the movement of the protective plate 610 may be performed through driving of a protective plate controller (not illustrated). Further, the protective plate controller (not illustrated) may control a speed of the spacing and/or the moving of the protective plate 610.

Directions of the spacing and the movement are not necessarily limited to directions of arrows illustrated in FIGS. 11C and 11D and may be controlled in other directions. For example, the protective plate 610 may be moved in a direction forming an acute angle with the ground.

Therefore, areas of the first area 110a and the second area 110b of the substrate 110 may be changed, and a reaction surface area between the etchant 217 and the substrate 110 may be changed. Thus, the first flat part P1, the inclined part “S”, and/or the second flat part P2 may be formed on the substrate 110. The etching of the substrate 110 is completed, and thus the etched substrate 1 may be manufactured.

In the protective plate removing operation S15′, the protective plate 610 positioned on the etched substrate 1 may be removed from the etched substrate 1. Accordingly, the etched substrate 1 may be finally obtained.

Further, after the series of operations according to the manufacturing method of the present disclosure, the etched substrate 1 may be chemically strengthened. The chemical strengthening process may be the same as/similar to the chemical strengthening process performed after the manufacturing method described above in FIGS. 4A to 4E.

Through the method of manufacturing the substrate according to FIG. 3, a process of manufacturing the etched substrate 1 may be simplified, and productivity may be improved. Further, manufacturing costs of the etched substrate 1 may be reduced through the process simplification.

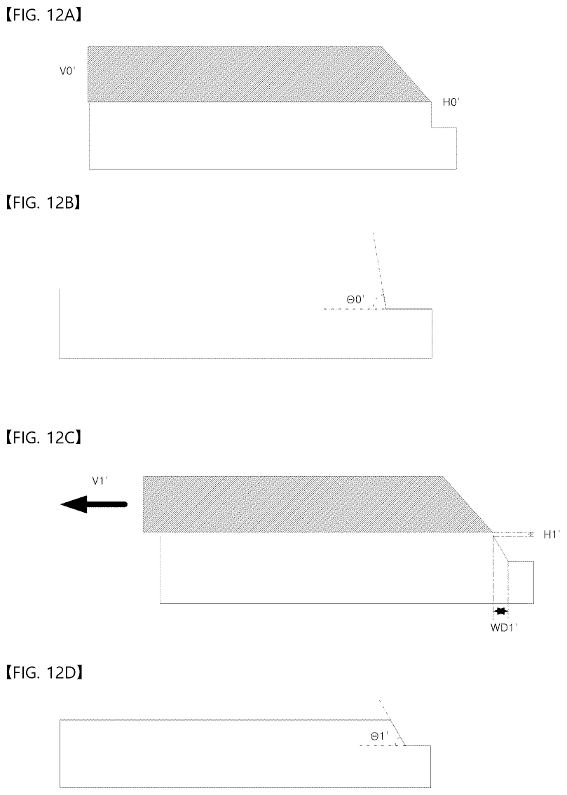

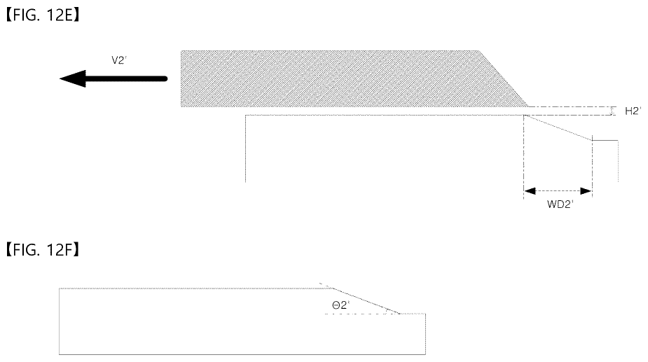

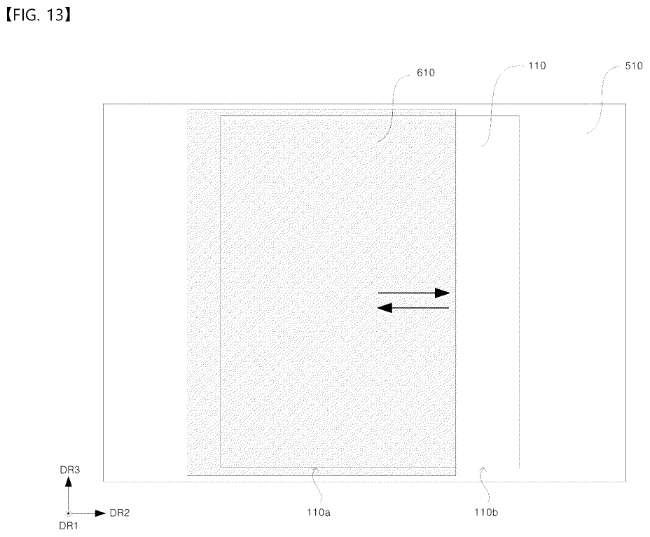

FIGS. 12A to 12F are cross-sectional views illustrating the angle Θ′ formed between the inclined part and the second flat part and the shapes of the first flat part, the inclined part, and the second flat part, which are changed according to the moving speed and the separation distance of the protective plate in the substrate that may be manufactured according to the present disclosure.

According to the embodiment of the present disclosure, when a separation distance H′ of the protective plate 610 is changed, a surface area of the substrate 110 exposed to the etchant 217 may be changed, and accordingly, the degree of etching on the substrate 110 may be changed. In this case, the width WD′ of the inclined part “S” formed on the substrate 110 may be changed. For example, when the separation distance H′ of the protective film 130 is increased, the surface area of the substrate 110 to which the etchant 217 is provided may be increased at the spaced portion of the protective plate 610. That is, the etched area on the substrate 110 may be increased. Thus, the width WD′ of the inclined part “S” formed on the substrate 110 may be increased. In contrast, when the separation distance H′ of the protective plate 610 is decreased, the surface area of the substrate 110 to which the etchant 217 is provided may be decreased at the spaced portion of the protective plate 610. That is, the etched area on the substrate 110 may be decreased. Thus, the width WD′ of the inclined part “S” formed on the substrate 110 may be decreased.

When a moving speed V′ of the protective plate 610 is changed, the protective plate 610 may move in the second direction DR2 parallel to the ground or the direction opposite to the second direction DR2, the amount of etchant 217 provided onto the substrate 110 may be changed, and accordingly, the degree of etching on the substrate 110 may be changed. In this case, the angle Θ′ formed between the inclined part “S” and the second flat part P2 formed on the substrate 110 may be changed. For example, when the moving speed V′ of the protective plate 610 is fast, the protective plate 610 may move so that a time interval during which the substrate 110 is exposed to the etchant 217 may be decreased for each portion in which the substrate 110 is exposed to the etchant 217. Accordingly, the etching may be uniformly performed, and thus the angle Θ′ between the inclined part “S” and the second flat part P2 formed on the substrate 110 may be decreased. Further, when the moving speed V′ of the protective plate 610 is slow, the protective plate 610 may move so that a time interval during which the substrate 110 is exposed to the etchant 217 may be increased for each portion in which the substrate 110 is exposed to the etchant 217. Accordingly, the etching may be unevenly performed, and thus the angle Θ′ between the inclined part “S” and the second flat part P2 formed on the substrate 110 may be increased.

FIGS. 12A, 12C, and 12E are cross-sectional views illustrating the etched substrate that may be manufactured according to the present disclosure when moving speeds of the protective plate 610 are V0′, V1′, and V2′, and separation distances thereof are H0′, H1′, and H2′.

FIG. 12B is a cross-sectional view of the etched substrate 1 that may be formed when the moving speed is set to V0′ and the separation distance is set to H0′ in FIG. 12A.

FIG. 12D is a cross-sectional view of the etched substrate 1 that may be formed when the moving speed is set to V1′ and the separation distance is set to H1′ in FIG. 12C.

FIG. 12F is a cross-sectional view of the etched substrate 1 that may be formed when the moving speed is set to V2′ and the separation distance is set to H2′ in FIG. 12E.

As described above, the angle formed between the inclined part “S” and the second flat part P2 may be affected by the moving speed V′ of the protective plate 610. For example, as the moving speed V′ of the protective plate 610 is increased, the angle Θ′ formed between the inclined part and the second flat part may be decreased.

As described above, the width WD′ of the inclined part may be affected by the separation distance H′ of the protective plate 610. For example, as the separation distance H′ of the protective plate 610 is increased, the width WD′ of the inclined part may be increased.

Comparing the moving speeds and the separation distances of the protective plate 610 illustrated in FIGS. 12A, 12C, and 12E, V0′<V1′<V2′ and H0′ <H1′<H2′.

Comparing the widths of the inclined part formed in the protective plate 610 illustrated in FIGS. 12A, 12C, and 12E, WD0′<WD1′<WD2′. Thus, as the separation distance of the protective plate 610 is increased, the width of the inclined part “S” may be increased.

Comparing the angles formed between the inclined part “S” and the second flat part P2 illustrated in FIGS. 12B, 12D, and 12F, Θ0′>Θ1′>Θ2′. Thus, as the moving speed of the protective plate 610 is increased, an inclination of the inclined part “S” may become gradually gentle.

In the present disclosure, using this principle, the separation distance and the moving speed of the protective plate 610 may be controlled through the spacing of the protective plate 610 in the first direction DR1 and the direction opposite to the first direction DR1 and the movement of the protective plate 610 in the second direction DR2 and the direction opposite to the second direction DR2. Thus, the etched substrate 1 in which the degree of etching on the substrate 110 may be adjusted and which has different thicknesses on both sides thereof may be formed.

In the embodiment of the present disclosure, the substrate 110 may be etched using the above-described method, and thus the etched substrate 1 having different thicknesses depending on areas thereof may be manufactured.

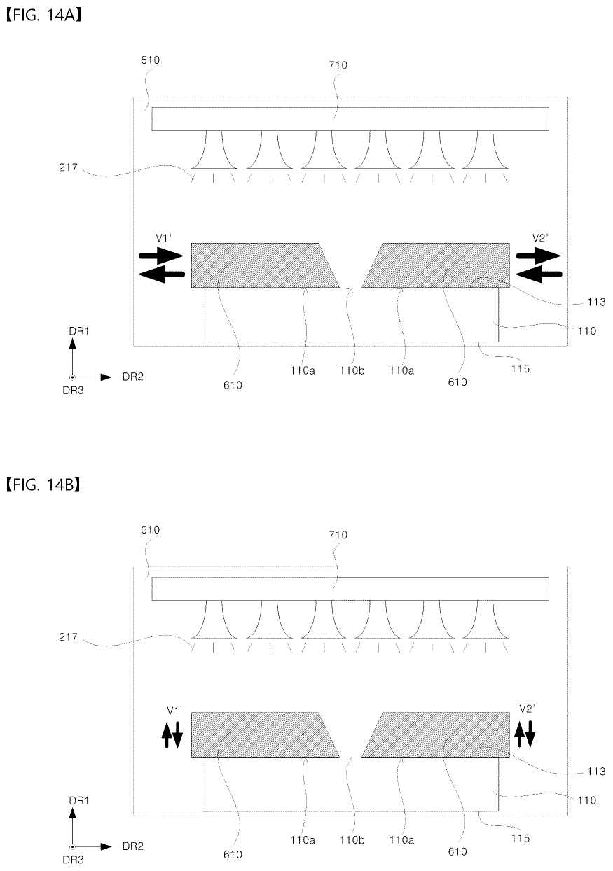

FIG. 13 is a plan view illustrating FIG. 11C in a DR2-DR3 plane.

Referring to FIG. 13, in the protective plate shifting operation S14′, the protective plate 610 may move in the second direction DR2 or the direction opposite to the second direction DR2. An area of the second area 110b of the substrate 110 may be adjusted through the movement of the protective plate 610. Accordingly, the etchant 217 may be provided on the second area 110b of the substrate 110. As the area of the second area 110b is adjusted, a reaction surface area between the etchant 217 and the surface of the substrate 110 may be changed, and the substrate 110 may be etched. The shapes of the first flat part P1, the inclined part “S” and/or the second flat part P2 that may be formed through the etching of the substrate 110 may be changed.

FIGS. 14A and 14B are cross-sectional views illustrating an embodiment including all an etching tank, a protective plate, and a chemical liquid spraying unit, in the protective plate shifting operation S14′ of the present disclosure.

Referring to FIGS. 14A and 14B, the substrate 110 may be positioned inside the etching tank 510. The plurality of protective plates 610 may be positioned on the first areas 110a of the substrate 110.

The etchant 217 may be provided on the second area 110b of the substrates 110. The second area 110b may correspond to a remaining area of the first surface 113 of the substrate 110 except for the first areas 110a covered with the protective plates 610.

As described above, the etchant 217 may be provided to the substrate 110 in various forms. For example, the etchant 217 may be provided on the second area 110b of the substrate 110 through the chemical liquid spraying unit 710. The protective plates 610 may be spaced in the first direction DR1 perpendicular to the substrate 110 or the direction opposite to the first direction DR1 or may be moved in the second direction DR2 parallel to the substrate 110 or the direction opposite to the second direction DR2. The spacing of the protective plates 610 and/or the movement of the protective plates 610 may be performed through the driving of the protective plate controller (not illustrated). Further, the protective plate controller (not illustrated) may control the speed of the spacing and/or the moving of the protective plates 610.

Directions of the spacing and the movement are not necessarily limited to directions of arrows illustrated in FIGS. 14A and 14B and may be controlled in other directions. For example, the protective plates 610 may be moved in a direction forming an acute angle with the ground.

The spacing direction and the spacing speed of each of the protective plates 610 may be different from the moving direction and the moving speed thereof. That is, the movement and the spacing of each of the protective plates 610 may be performed independently.

The area of the second area 110b of the substrate 110 on the first surface 113 may be adjusted through the movement and the spacing of the protective plates 610. As the area of the second area 110b is adjusted, a reaction surface area between the etchant 217 and the surface of the substrate 110 may be changed, and the substrate 110 may be etched. The shapes of the first flat part P1, the inclined part “S” and/or the second flat part P2 that may be formed through the etching of the substrate 110 may be changed.

The folding part “F” may be formed at a portion of the substrate 110 through this process, and accordingly, the foldable substrate 111 having the folding part “F” having a desired shape may be manufactured.

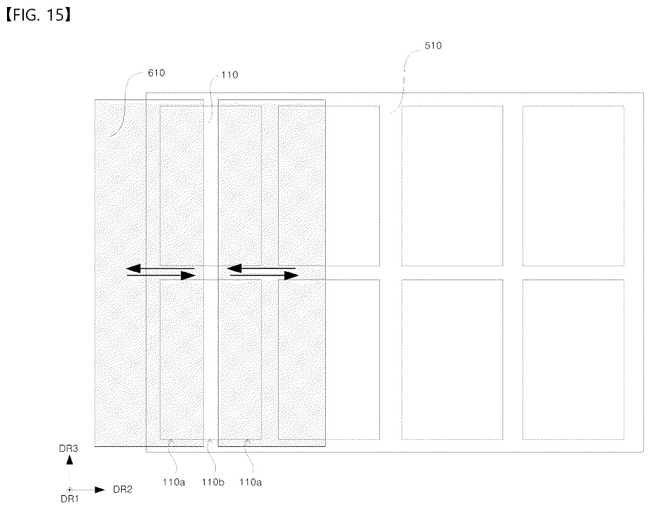

FIG. 15 is a plan view illustrating including all the etching tank, the protective plate, and the chemical liquid spraying unit in the DR2-DR3 plane in a protective plate shifting operation S14′ of the present disclosure.

Referring to FIG. 15, the plurality of substrates 110 may be positioned inside the etching tank 510. The plurality of protective plates 610 may be positioned on the first areas 110a of the substrates 110. Here, some of the plurality of protective plates 610 may cover the plurality of first areas 110a.

The etchant 217 may be provided on the second areas 110b of the substrates 110. The second areas 110b may correspond to a remaining area of the first surface 113 of the substrate 110 except for the first areas 110a covered with the protective plates 610.

As described above, the etchant 217 may be provided on the second areas 110b of the substrates 110 in various forms. For example, the etchant 217 may be provided on the second areas 110b of the substrates 110 through the chemical liquid spraying unit 710.

The etchant 217 may be provided to at least some of the substrates 110. The temperature, the spraying speed and/or the spraying direction of the etchant 217 may be adjusted through the chemical liquid spraying unit 710, and accordingly, the etchant 217 may be provided to only some of the substrates 110.

At least some of the protective plates 610 may be spaced in the first direction DR1 perpendicular to the substrates 110 or the direction opposite to the first direction DR1 or may be moved in the second direction DR2 parallel to the substrates 110 or the direction opposite to the second direction DR2. The spacing of the at least some of the protective plates 610 and/or the movement of the at least some of the protective plates 610 may be performed through the driving of the protective plate controller (not illustrated). Further, the protective plate controller (not illustrated) may control the speed of the spacing and/or the moving of the at least some of the protective plates 610.

The spacing direction (not indicated by an arrow) and the moving direction are not necessarily limited to a direction of an arrow illustrated in FIG. 15 and may be controlled in other directions. For example, the protective plates 610 may be moved in a direction forming an acute angle with the ground.

The spacing direction and the spacing speed of each of the protective plates 610 may be different from the moving direction and the moving speed thereof. That is, the movement and the spacing of each of the protective plates 610 may be performed independently.

The other manufacturing method may be the same as/similar to the manufacturing method described above in FIGS. 14A and 14B.

The folding parts “F” may be formed at portions of the substrates 110 through this process, and accordingly, the plurality of foldable substrates 111 having the folding parts “F” having a desired shape may be manufactured.

In the foldable substrates 111, visibility of a reflective surface in the inclined part “S” may be improved, and screen distortion or visibility of the boundary may be minimized.

According to an embodiment of the present disclosure, the amount of etchant provided to a substrate may be adjusted by changing an adhesive force of a protective film adhesive layer attached to the substrate. Accordingly, the degree of etching of the substrate may be adjusted.

According to an embodiment of the present disclosure, a flow rate and direction of an etchant may be adjusted using a chemical liquid controller that adjusts the flow rate and direction of the etchant. Accordingly, the degree of etching of the substrate may be adjusted.

According to an embodiment of the present disclosure, a gripping part that peels off an end of a protective film and controls a peeling speed of the end may be used. Accordingly, a degree of etching of a substrate may be adjusted, and ultimately, an inclined part having a desired angle and a desired width may be implemented.

According to an embodiment of the present disclosure, a peeling controller that controls a peeling speed of an end of a protective film may be used. Accordingly, a degree of etching of a substrate may be adjusted, and ultimately, an inclined part having a desired angle and a desired width may be implemented.

According to an embodiment of the present disclosure, a protective plate may be provided on a first area. Further, the protective plate may be spaced or moved by a protective plate controller. Therefore, a reaction surface area between an etchant and a substrate may be changed.

According to an embodiment of the present disclosure, a chemical liquid spraying unit that adjusts a temperature, a spraying intensity, and a spraying direction of an etchant may be used to adjust etching of a substrate.

According to an embodiment of the present disclosure, shapes of an inclined part, a first flat part, and/or a second flat part formed on a substrate may be changed by controlling a spacing speed and a moving speed of a protective plate. Accordingly, the inclined part having a desired angle and a desired width may be implemented.

Although the description has been made above with reference to an embodiment of the present disclosure, it may be understood that those skilled in the art or those having ordinary knowledge in the art may variously modify and change the present disclosure without departing from the spirit and technical scope of the present disclosure described in the appended claims.

Accordingly, the technical scope of the present disclosure is not limited to the detailed description of the specification, but should be defined by the appended claims.

What is claimed is:

1. A method of manufacturing a substrate, the method comprising:
attaching a protective film having an adhesive layer formed on one surface thereof onto the substrate;
providing an etchant onto the substrate to which the protective film is attached;
forming a first flat part, an inclined part, and a second flat part by peeling off an end of the protective film and by changing a reaction surface area between the etchant and the substrate; and
removing the protective film.

2. The method of claim 1, wherein a spacing speed of the end of the protective film is controlled according to an adhesive force of the adhesive layer.

3. The method of claim 1, wherein the protective film is acid resistant.

4. The method of claim 1, wherein a chemical liquid controller configured to adjust a flow rate and a direction of the etchant is included.

5. The method of claim 4, wherein the chemical liquid controller includes at least one of:
a chamber support; or
an etching chemical liquid spraying nozzle.

6. The method of claim 1, wherein a gripping part configured to grip the end of the protective film and apply a force in a first direction perpendicular to one surface of the substrate to space the end of the protective film apart from the one surface of the substrate is included.

7. The method of claim 6, wherein the gripping part controls a peeling speed of the end of the protective film to adjust an angle of the inclined part.

8. The method of claim 1, wherein a peeling controller that is in contact with an upper surface of the protective film and presses the end of the protective film in a direction opposite to a first direction perpendicular to one surface of the substrate when the end of the protective film is peeled off is included.

9. The method of claim 1, wherein the peeling controller includes any one of a roller or a squeeze.

10. A method of manufacturing a substrate, the method comprising:
a first operation of positioning a protective plate on a surface of the substrate to cover a first area on the surface of the substrate with the protective plate; and
a second operation of reacting the substrate and an etchant by providing the etchant to a second area of the surface of the substrate except for the first area,
wherein, in the second operation, a reaction surface area between the surface of the substrate and the etchant is changed by moving the protective plate on the surface of the substrate.

11. The method of claim 10 wherein the second operation includes a process of spacing the protective plate from the surface of the substrate in a first direction perpendicular to the substrate or a direction opposite to the first direction.

12. The method of claim 11, wherein a spacing speed of the protective plate is controlled.

13. The method of claim 10, wherein the second operation includes a process of moving the protective plate in a second direction parallel to the substrate or a direction opposite to the second direction.

14. The method of claim 13, wherein a moving speed of the protective plate is controlled.

15. The method of claim 10, wherein the protective plate includes an acid-resistant material.

16. The method of claim 10, wherein a chemical liquid spraying unit configured to adjust a temperature, a spraying speed, and/or a spraying direction of the etchant is included.

17. A method of manufacturing a substrate, the method comprising:
a first operation of positioning a plurality of protective plates on a surface of the substrate to cover first areas on the surface of the substrate; and
a second operation of reacting the substrate and an etchant by providing the etchant to a remaining second area except for the first areas,
wherein, in the second operation, at least some of the plurality of protective plates are moved onto the surface of the substrate to change a reaction surface area between the etchant and the surface of the substrate.

18. The method of claim 17, comprising:
a process of spacing the at least some of the plurality of protective plates in a first direction perpendicular to the substrate or a direction opposite to the first direction; and/or
a process of moving the at least some of the plurality of protective plates in a second direction parallel to the substrate or a direction opposite to the second direction.

19. The method of claim 17, wherein a chemical liquid spraying unit configured to adjust a temperature, a spraying speed, and/or a spraying direction of the etchant is included.
